(19) United States
(12) Patent Application Publication
(10) Pub. No.: US 2021/0043448 A1
(43) Pub. Date: Feb. 11, 2021

(54) Method and Apparatus for Selective Deposition of Dielectric Films

(71) Applicant: Applied Materials, Inc., Santa Clara, CA (US)

(72) Inventors: Ning Li, San Jose, CA (US); Mihaela A. Balseanu, Sunnyvale, CA (US); Li-Qun Xia, Cupertino, CA (US); Dongqing Yang, Pleasonton, CA (US); Lala Zhu, Fremont, CA (US); Malcolm J. Bevan, Santa Clara, CA (US); Theresa Kramer Guarini, San Jose, CA (US); Wenbo Yan, Sunnyvale, CA (US)

(73) Assignee: Applied Materials, Inc., Santa Clara, CA (US)

(21) Appl. No.: 17/081,256

(22) Filed: Oct. 27, 2020

Related U.S. Application Data
(62) Division of application No. 15/879,008, filed on Jan. 24, 2018.
(60) Provisional application No. 62/449,668, filed on Jan. 24, 2017.

(51) Int. Cl. H01L 21/02; H01L 21/3105; C23C 16/458; C23C 16/455; C23C 16/04; C23C 16/02; C23C 16/56

(52) U.S. Cl. CPC H01L 21/02271; H01L 21/3105; C23C 16/458; C23C 16/45551; H01L 21/0228; H01L 21/32; C23C 16/04; H01L 21/02299; C23C 16/4583; C23C 16/0245; C23C 16/56; H01L 21/02312

(57) ABSTRACT

Processing platforms having a central transfer station with a robot and an environment having greater than or equal to about 0.1% by weight water vapor, a pre-clean chamber connected to a side of the transfer station and a batch processing chamber connected to a side of the transfer station. The processing platform configured to pre-clean a substrate to remove native oxides from a first surface, form a blocking layer using a alkylsilane and selectively deposit a film. Methods of using the processing platforms and processing a plurality of wafers are also described.

### CROSS-REFERENCE TO RELATED APPLICATIONS

This application is a divisional application of U.S. patent application Ser. No. 15/879,008, filed Jan. 24, 2018, which claims priority to U.S. Provisional Application No. 62/449,668, filed Jan. 24, 2017, the entire disclosures of which are hereby incorporated by reference.

### TECHNICAL FIELD

The present disclosure relates generally to apparatus and methods for depositing thin films. In particular, the disclosure relates to integrated atomic layer deposition tools and methods for selectively depositing a film.

### BACKGROUND

Integrated circuits are made possible by processes which produce intricately patterned material layers on substrate surfaces. Producing patterned materials on a substrate requires controlled methods for deposition and removal of material layers. Modern semiconductor manufacturing processing applies increasing emphasis on the integration of films without air breaks between process steps. Such a requirement poses a challenge for equipment manufacturers to allow integration of various process chambers into a single tool.

One process that has become popular for deposition of thin films is atomic layer deposition (ALD). Atomic layer deposition is a method in which a substrate is exposed to a precursor which chemisorbs to the substrate surface followed by a reactant which reacts with the chemisorbed precursor. ALD processes are self-limiting and can provide molecular level control of film thicknesses. However, ALD processing can be time consuming due to the need to purge the reaction chamber between exposures to the precursors and reactants.

Selective deposition processes are becoming more frequently employed because of the need for patterning applications for semiconductors. Traditionally, patterning in the microelectronics industry has been accomplished using various lithography and etch processes. However, since lithography is becoming exponentially complex and expensive the use of selective deposition to deposit features is becoming much more attractive.

As device sizes continue to decrease to less than the 10 nm regime, traditional patterning processes using photolithography technology is becoming more challenging. Non-precise patterning and degraded device performance are more prevalent at lower device sizes. Additionally, the multiple patterning technologies also make fabrication processes complicated and more expensive.

Therefore, there is a need in the art for apparatus and methods to selectively deposit a film onto one surface selectively over a different surface.

### SUMMARY

One or more embodiments of the disclosure are directed to processing platforms comprising a central transfer station, a pre-clean chamber and a batch processing chamber. The central transfer station has a robot therein and a plurality of sides. The pre-clean chamber is connected to a first side of the central transfer station. The pre-clean chamber is configured to perform one or more of a wet etch process or a dry etch process. The batch processing chamber is connected to a second side of the central transfer station. The batch processing chamber has a plurality of process regions separated by gas curtains. The batch processing chamber includes a susceptor assembly configured to support and rotate a plurality of substrates around a central axis so that the substrates move through the plurality of process regions. At least the central transfer station has an environment comprising greater than or equal to about 0.1% by weight water vapor in an inert gas.

Further embodiments of the disclosure are directed to methods of depositing a film. A substrate comprising a first substrate surface including hydroxyl-terminated surface and a second substrate surface including a hydrogen-terminated surface is provided. The substrate is exposed to a passivation agent to react with the hydroxyl-terminated surface to form a blocking layer on the first surface. The passivation agent comprises an alkylsilane. The substrate is exposed to one or more deposition gases to deposit a film on second substrate surface selectively over the first surface. The film is exposed to a helium decoupled plasma to improve a quality of the film. The substrate is moved at least once through a central transfer station comprising an environment with an inert gas with greater than or equal to about 0.1% water vapor by weight.

Further embodiments of the disclosure are directed to methods of depositing a film. A substrate comprising a first substrate surface including hydroxyl-terminated surface and a second substrate surface including a hydrogen-terminated surface is provided. The substrate surface is exposed to an etch process to remove native oxides from the second surface. The etch process comprises one or more of dilute HF or a plasma-based etch. The substrate is exposed to a passivation agent to react with the hydroxyl-terminated surface to form a blocking layer. The passivation agent comprises an alkylsilane having a general formula SiR₄, where each R is independently a C1-C6 alkyl, a substituted or unsubstituted amine, a substituted or unsubstituted cyclic amine, the alkylsilane comprising substantially no Si—H bonds, where at least one R group is a substituted or unsubstituted cyclic amine with a ring having in the range of 4 to 10 atoms where one atom is a nitrogen atom. The substrate is exposed to one or more deposition gases to deposit a film on second substrate surface selectively over the first surface. The film comprises silicon and one or more of oxygen, nitrogen or carbon. The film is exposed to a helium decoupled plasma to improve quality of the film. The substrate is moved at least once through a central transfer station having an environment comprising an inert gas with greater than or equal to about 0.1% by weight water vapor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a schematic view of a processing platform in accordance with one or more embodiment of the disclosure;

FIG. 2 shows a cross-sectional view of a batch processing chamber in accordance with one or more embodiment of the disclosure;

FIG. 3 shows a partial perspective view of a batch processing chamber in accordance with one or more embodiment of the disclosure;

FIG. 4 shows a schematic view of a batch processing chamber in accordance with one or more embodiment of the disclosure;

FIG. 5 shows a schematic view of a portion of a wedge shaped gas distribution assembly for use in a batch processing chamber in accordance with one or more embodiment of the disclosure;

FIG. 6 shows a schematic view of a batch processing chamber in accordance with one or more embodiment of the disclosure; and

FIG. 7 shows a schematic representation of a method in accordance with one or more embodiment of the disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

A “wafer” or “substrate” as used herein refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

One or more embodiments of the disclosure provide methods of forming dielectric films selectively on certain areas of the processing wafer based on the surface terminating chemical groups. Atomic layer deposition (ALD) film growth can be done by traditional time-domain processing or by spatial ALD in a batch processing chamber. Some embodiments use a surface treatment to ensure that different terminating groups are present on the device wafer so that a following ALD film growth will be differentiated based on the difference surfaces. For example, to prepare a bare Si surface terminated with Si—H groups, dilute HF wet clean or a plasma-based dry clean can be used to remove native oxide on Si surface and form Si—H bonds. To prepare a passivated surface that can block ALD film growth, a hydrophobic surface monolayer can be formed on silicon oxide surface. For example, alkylamino silane can be adsorbed onto silicon oxide surface to form alkylsilyl groups on SiO surface. The ALD film growth chemistry of some embodiments is based on silicon halide and ammonia reactions which can selectively grow on bare Si surface but not a passivated SiO surface. The maximum thickness achievable by some embodiments is about 100 Å growth on bare Si, with substantially no film growth on the passivated SiO surface. Periodic SiO surface regeneration and passivation could be used to make thicker growth on bare Si than SiO.

In some embodiments, a low k film with composition of Si/C/O/N can also be selective deposited. SiCON deposition of some embodiments uses a C containing Si precursor, ammonia and an oxidation agent, such as, O₂, O₃ or N₂O.

In some embodiments, plasma treatment is used as a way to improve an as-deposited film property. For example, thermally grown SiN film could possess high wet etch rate. A decoupled plasma treatment using helium has been surprisingly shown to dramatically improve film properties.

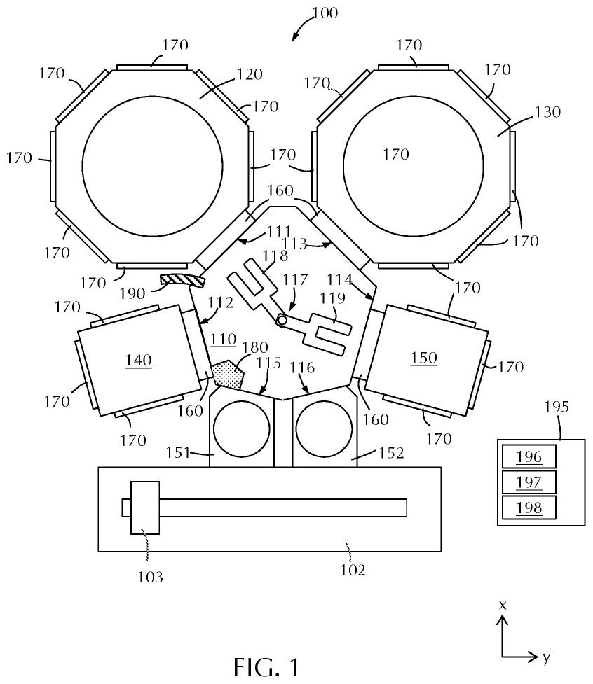

FIG. 1 shows a processing platform 100 in accordance with one or more embodiment of the disclosure. The embodiment shown in FIG. 1 is merely representative of one possible configuration and should not be taken as limiting the scope of the disclosure. For example, in some embodiments, the processing platform 100 has different numbers of process chambers, buffer chambers and robot configurations.

The processing platform 100 includes a central transfer station 110 which has a plurality of sides 111, 112, 113, 114, 115, 116. The transfer station 110 shown has a first side 111, a second side 112, a third side 113, a fourth side 114, a fifth side 115 and a sixth side 116. Although six sides are shown, those skilled in the art will understand that there can be any suitable number of sides to the transfer station 110 depending on, for example, the overall configuration of the processing platform 100.

The transfer station 110 has a robot 117 positioned therein. The robot 117 can be any suitable robot capable of moving a wafer during processing. In some embodiments, the robot 117 has a first arm 118 and a second arm 119. The first arm 118 and second arm 119 can be moved independently of the other arm. The first arm 118 and second arm 119 can move in the x-y plane and/or along the z-axis. In some embodiments, the robot 117 includes a third arm or a fourth arm (not shown). Each of the arms can move independently of other arms.

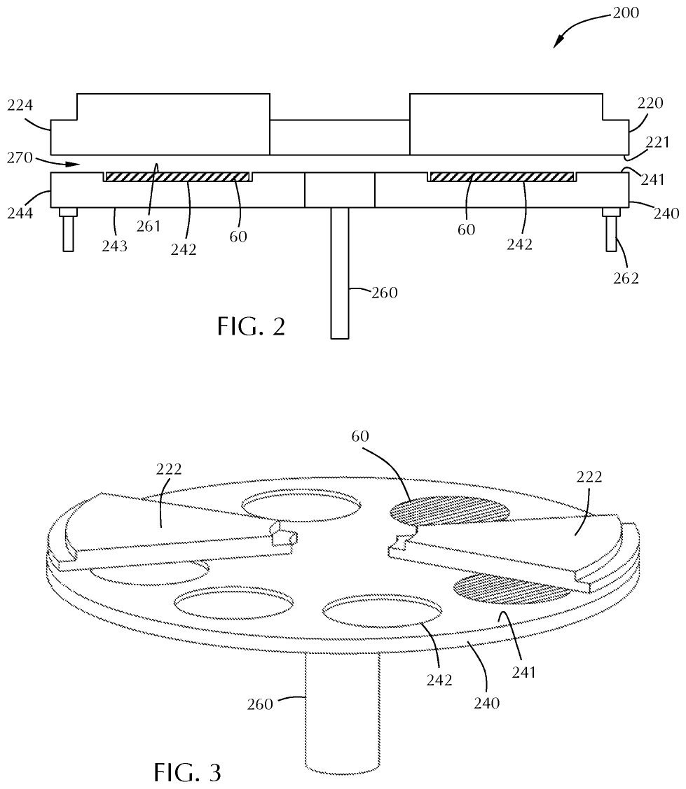

A batch processing chamber 120 can be connected to a first side 111 of the central transfer station 110. The batch processing chamber 120 can be configured to process x wafers at a time for a batch time. In some embodiments, the batch processing chamber 120 can be configured to process in the range of about four (x=4) to about 12 (x=12) wafers at the same time. In some embodiments, the batch processing chamber 120 is configured to process six (x=6) wafers at the same time. As will be understood by the skilled artisan, while the batch processing chamber 120 can process multiple wafers between loading/unloading of an individual wafer, each wafer may be subjected to different process conditions at any given time. For example, a spatial atomic layer deposition chamber, like that shown in FIGS. 2 through 6, expose the wafers to different process conditions in different processing regions so that as a wafer is moved through each of the regions, the process is completed.

FIG. 2 shows a cross-section of a processing chamber 200 including a gas distribution assembly 220, also referred to as injectors or an injector assembly, and a susceptor assembly 240. The gas distribution assembly 220 is any type of gas delivery device used in a processing chamber. The gas distribution assembly 220 includes a front surface 221 which faces the susceptor assembly 240. The front surface 221 can have any number or variety of openings to deliver a flow of gases toward the susceptor assembly 240. The gas distribution assembly 220 also includes an outer peripheral edge 224 which in the embodiments shown, is substantially round.

The specific type of gas distribution assembly 220 used can vary depending on the particular process being used. Embodiments of the disclosure can be used with any type of processing system where the gap between the susceptor and the gas distribution assembly is controlled. While various types of gas distribution assemblies can be employed (e.g., showerheads), embodiments of the disclosure may be particularly useful with spatial gas distribution assemblies which have a plurality of substantially parallel gas channels. As used in this specification and the appended claims, the term “substantially parallel” means that the elongate axis of the gas channels extend in the same general direction. There can be slight imperfections in the parallelism of the gas channels. In a binary reaction, the plurality of substantially parallel gas channels can include at least one first reactive gas A channel, at least one second reactive gas B channel, at least one purge gas P channel and/or at least one vacuum V channel. The gases flowing from the first reactive gas A channel(s), the second reactive gas B channel(s) and the purge gas P channel(s) are directed toward the top surface of the wafer. Some of the gas flow moves horizontally across the surface of the wafer and out of the process region through the purge gas P channel(s). A substrate moving from one end of the gas distribution assembly to the other end will be exposed to each of the process gases in turn, forming a layer on the substrate surface.

In some embodiments, the gas distribution assembly 220 is a rigid stationary body made of a single injector unit. In one or more embodiments, the gas distribution assembly 220 is made up of a plurality of individual sectors (e.g., injector units 222), as shown in FIG. 3. Either a single piece body or a multi-sector body can be used with the various embodiments of the disclosure described.

A susceptor assembly 240 is positioned beneath the gas distribution assembly 220. The susceptor assembly 240 includes a top surface 241 and at least one recess 242 in the top surface 241. The susceptor assembly 240 also has a bottom surface 243 and an edge 244. The recess 242 can be any suitable shape and size depending on the shape and size of the substrates 60 being processed. In the embodiment shown in FIG. 2, the recess 242 has a flat bottom to support the bottom of the wafer; however, the bottom of the recess can vary. In some embodiments, the recess has step regions around the outer peripheral edge of the recess which are sized to support the outer peripheral edge of the wafer. The amount of the outer peripheral edge of the wafer that is supported by the steps can vary depending on, for example, the thickness of the wafer and the presence of features already present on the back side of the wafer.

In some embodiments, as shown in FIG. 2, the recess 242 in the top surface 241 of the susceptor assembly 240 is sized so that a substrate 60 supported in the recess 242 has a top surface 61 substantially coplanar with the top surface 241 of the susceptor 240. As used in this specification and the appended claims, the term “substantially coplanar” means that the top surface of the wafer and the top surface of the susceptor assembly are coplanar within ±0.2 mm. In some embodiments, the top surfaces are coplanar within 0.5 mm, ±0.4 mm, ±0.35 mm, ±0.30 mm, ±0.25 mm, ±0.20 mm, ±0.15 mm, ±0.10 mm or ±0.05 mm.

The susceptor assembly 240 of FIG. 2 includes a support post 260 which is capable of lifting, lowering and rotating the susceptor assembly 240. The susceptor assembly may include a heater, or gas lines, or electrical components within the center of the support post 260. The support post 260 may be the primary means of increasing or decreasing the gap between the susceptor assembly 240 and the gas distribution assembly 220, moving the susceptor assembly 240 into proper position. The susceptor assembly 240 may also include fine tuning actuators 262 which can make micro-adjustments to susceptor assembly 240 to create a predetermined gap 270 between the susceptor assembly 240 and the gas distribution assembly 220.

In some embodiments, the gap 270 distance is in the range of about 0.1 mm to about 5.0 mm, or in the range of about 0.1 mm to about 3.0 mm, or in the range of about 0.1 mm to about 2.0 mm, or in the range of about 0.2 mm to about 1.8 mm, or in the range of about 0.3 mm to about 1.7 mm, or in the range of about 0.4 mm to about 1.6 mm, or in the range of about 0.5 mm to about 1.5 mm, or in the range of about 0.6 mm to about 1.4 mm, or in the range of about 0.7 mm to about 1.3 mm, or in the range of about 0.8 mm to about 1.2 mm, or in the range of about 0.9 mm to about 1.1 mm, or about 1 mm.

The processing chamber 200 shown in the Figures is a carousel-type chamber in which the susceptor assembly 240 can hold a plurality of substrates 60. As shown in FIG. 3, the gas distribution assembly 220 may include a plurality of separate injector units 222, each injector unit 222 being capable of depositing a film on the wafer, as the wafer is moved beneath the injector unit. Two pie-shaped injector units 222 are shown positioned on approximately opposite sides of and above the susceptor assembly 240. This number of injector units 222 is shown for illustrative purposes only. It will be understood that more or less injector units 222 can be included. In some embodiments, there are a sufficient number of pie-shaped injector units 222 to form a shape conforming to the shape of the susceptor assembly 240. In some embodiments, each of the individual pie-shaped injector units 222 may be independently moved, removed and/or replaced without affecting any of the other injector units 222. For example, one segment may be raised to permit a robot to access the region between the susceptor assembly 240 and gas distribution assembly 220 to load/unload substrates 60.

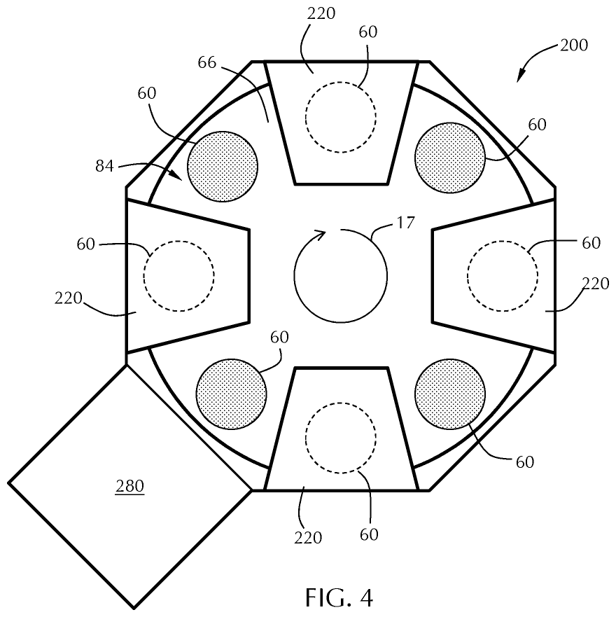

Processing chambers having multiple gas injectors can be used to process multiple wafers simultaneously so that the wafers experience the same process flow. For example, as shown in FIG. 4, the processing chamber 200 has four gas injector assemblies and four substrates 60. At the outset of processing, the substrates 60 can be positioned between the gas distribution assemblies 220. Rotating 17 the susceptor assembly 240 by 45° will result in each substrate 60 which is between gas distribution assemblies 220 to be moved to a gas distribution assembly 220 for film deposition, as illustrated by the dotted circle under the gas distribution assemblies 220. An additional 45° rotation would move the substrates 60 away from the gas distribution assemblies 220. The number of substrates 60 and gas distribution assemblies 220 can be the same or different. In some embodiments, there are the same numbers of wafers being processed as there are gas distribution assemblies. In one or more embodiments, the number of wafers being processed are fraction of or an integer multiple of the number of gas distribution assemblies. For example, if there are four gas distribution assemblies, there are 4x wafers being processed, where x is an integer value greater than or equal to one. In an exemplary embodiment, the gas distribution assembly 220 includes eight process regions separated by gas curtains and the susceptor assembly 240 can hold six wafers.

The processing chamber 200 shown in FIG. 4 is merely representative of one possible configuration and should not be taken as limiting the scope of the disclosure. Here, the processing chamber 200 includes a plurality of gas distribution assemblies 220. In the embodiment shown, there are four gas distribution assemblies 220 (also called injector assemblies) evenly spaced about the processing chamber 200. The processing chamber 200 shown is octagonal; however, those skilled in the art will understand that this is one possible shape and should not be taken as limiting the scope of the disclosure. The gas distribution assemblies 220 shown are trapezoidal, but can be a single circular component or made up of a plurality of pie-shaped segments, like that shown in FIG. 3.

The embodiment shown in FIG. 4 includes a load lock chamber 280 (also referred to as factory interface), or an auxiliary chamber like a buffer station. The load lock chamber 280 is connected to a side of the processing chamber 200 to allow, for example the substrates (also referred to as substrates 60) to be loaded/unloaded from the chamber 200. A wafer robot may be positioned in the load lock chamber 280 to move the substrate onto the susceptor.

Rotation of the carousel (e.g., the susceptor assembly 240) can be continuous or intermittent (discontinuous). In continuous processing, the wafers are constantly rotating so that they are exposed to each of the injectors in turn. In discontinuous processing, the wafers can be moved to the injector region and stopped, and then to the region 84 between the injectors and stopped. For example, the carousel can rotate so that the wafers move from an inter-injector region across the injector (or stop adjacent the injector) and on to the next inter-injector region where the carousel can pause again. Pausing between the injectors may provide time for additional processing steps between each layer deposition (e.g., exposure to plasma).

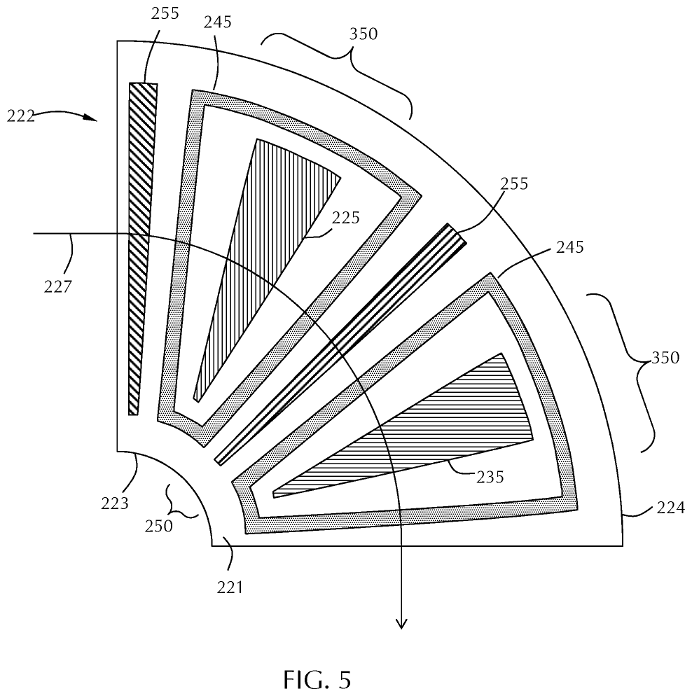

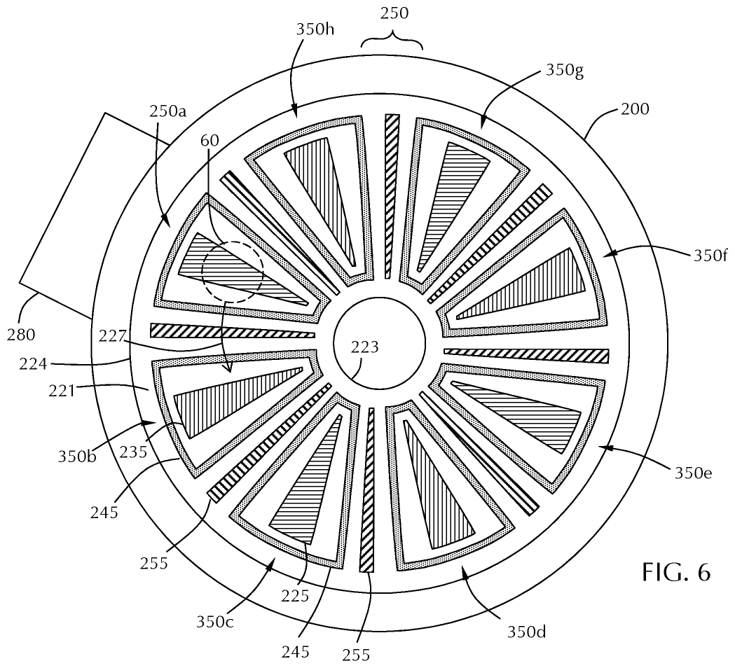

FIG. 5 shows a sector or portion of a gas distribution assembly 220, which may be referred to as an injector unit 222. The injector units 222 can be used individually or in combination with other injector units. For example, as shown in FIG. 6, four of the injector units 222 of FIG. 5 are combined to form a single gas distribution assembly 220. (The lines separating the four injector units are not shown for clarity.) While the injector unit 222 of FIG. 5 has both a first reactive gas port 225 and a second gas port 235 in addition to purge gas ports 255 and vacuum ports 245, an injector unit 222 does not need all of these components.

Referring to both FIGS. 5 and 6, a gas distribution assembly 220 in accordance with one or more embodiment may comprise a plurality of sectors (or injector units 222) with each sector being identical or different. The gas distribution assembly 220 is positioned within the processing chamber and comprises a plurality of elongate gas ports 225, 235, 245 in a front surface 221 of the gas distribution assembly 220. The plurality of elongate gas ports 225, 235, 245, 255 extend from an area adjacent the inner peripheral edge 223 toward an area adjacent the outer peripheral edge 224 of the gas distribution assembly 220. The plurality of gas ports shown include a first reactive gas port 225, a second gas port 235, a vacuum port 245 which surrounds each of the first reactive gas ports and the second reactive gas ports and a purge gas port 255.

With reference to the embodiments shown in FIG. 5 or 6, when stating that the ports extend from at least about an inner peripheral region to at least about an outer peripheral region, however, the ports can extend more than just radially from inner to outer regions. The ports can extend tangentially as vacuum port 245 surrounds reactive gas port 225 and reactive gas port 235. In the embodiment shown in FIGS. 5 and 6, the wedge shaped reactive gas ports 225, 235 are surrounded on all edges, including adjacent the inner peripheral region and outer peripheral region, by a vacuum port 245.

Referring to FIG. 5, as a substrate moves along path 227, each portion of the substrate surface is exposed to the various reactive gases. To follow the path 227, the substrate will be exposed to, or “see”, a purge gas port 255, a vacuum port 245, a first reactive gas port 225, a vacuum port 245, a purge gas port 255, a vacuum port 245, a second gas port 235 and a vacuum port 245. Thus, at the end of the path 227 shown in FIG. 5, the substrate has been exposed to the first reactive gas from the first reactive gas port 225 and the second reactive gas from the second reactive gas port 235 to form a layer. The injector unit 222 shown makes a quarter circle but could be larger or smaller. The gas distribution assembly 220 shown in FIG. 6 can be considered a combination of four of the injector units 222 of FIG. 4 connected in series.

The injector unit 222 of FIG. 5 shows a gas curtain 250 that separates the reactive gases. The term “gas curtain” is used to describe any combination of gas flows or vacuum that separate reactive gases from mixing. The gas curtain 250 shown in FIG. 5 comprises the portion of the vacuum port 245 next to the first reactive gas port 225, the purge gas port 255 in the middle and a portion of the vacuum port 245 next to the second gas port 235. This combination of gas flow and vacuum can be used to prevent or minimize gas phase reactions of the first reactive gas and the second reactive gas.

Referring to FIG. 6, the combination of gas flows and vacuum from the gas distribution assembly 220 form a separation into a plurality of process regions 350. The process regions are roughly defined around the individual gas ports 225, 235 with the gas curtain 250 between 350. The embodiment shown in FIG. 6 makes up eight separate process regions 350 with eight separate gas curtains 250 between. A processing chamber can have at least two process regions. In some embodiments, there are at least three, four, five, six, seven, eight, nine, 10, 11 or 12 process regions.

During processing a substrate may be exposed to more than one process region 350 at any given time. However, the portions that are exposed to the different process regions will have a gas curtain separating the two. For example, if the leading edge of a substrate enters a process region including the second gas port 235, a middle portion of the substrate will be under a gas curtain 250 and the trailing edge of the substrate will be in a process region including the first reactive gas port 225.

A factory interface (load lock chamber 280) is shown connected to the processing chamber 200. A substrate 60 is shown superimposed over the gas distribution assembly 220 to provide a frame of reference. The substrate 60 may often sit on a susceptor assembly to be held near the front surface 221 of the gas distribution assembly 220. The substrate 60 is loaded via the factory interface (load lock chamber 280) into the processing chamber 200 onto a substrate support or susceptor assembly (see FIG. 4). The substrate 60 can be shown positioned within a process region because the substrate is located adjacent the first reactive gas port 225 and between two gas curtains 250a, 250b. Rotating the substrate 60 along path 227 will move the substrate counter-clockwise around the processing chamber 200. Thus, the substrate 60 will be exposed to the first process region 350a through the eighth process region 350h, including all process regions between.

Some embodiments of the disclosure are directed to processing methods comprising a processing chamber 200 with a plurality of process regions 350a-350h with each process region separated from an adjacent region by a gas curtain 250. For example, the processing chamber shown in FIG. 6. The number of gas curtains and process regions within the processing chamber can be any suitable number depending on the arrangement of gas flows. The embodiment shown in FIG. 6 has eight gas curtains 250 and eight process regions 350a-350h.

Referring back to FIG. 1, the processing platform 100 includes a pre-clean chamber 140 connected to a second side 112 of the central transfer station 110. The pre-clean chamber 140 is configured to expose the wafers to one or more of a wet etch comprising dilute (1%) hydrofluoric acid or a dry etch comprising a plasma-based etch. For example, a plasma-based etch process might expose the substrate surface a mixture of ammonia and HF.

In some embodiments, the processing platform further comprises a second batch processing chamber 130 connected to a third side 113 of the central transfer station 110. The second batch processing chamber 130 can be configured similarly to the batch processing chamber 120, or can be configured to perform a different process or to process different numbers of substrates.

The second batch processing chamber 130 can be the same as the first batch processing chamber 120 or different. In some embodiments, the first batch processing chamber 120 and the second batch processing chamber 130 are configured to perform the same process with the same number of wafers in the same batch time so that x and y (the number of wafers in the second batch processing chamber 130) are the same and the first batch time and second batch time (of the second batch processing chamber 130) are the same. In some embodiments, the first batch processing chamber 120 and the second batch processing chamber 130 are configured to have one or more of different numbers of wafers (x not equal to y), different batch times, or both.

In the embodiment shown in FIG. 1, the processing platform 100 includes a second pre-clean chamber 150 connected to a fourth side 114 of the central transfer station 110. The second pre-clean chamber 150 can be the same as the pre-clean chamber 140 or different. In some embodiments, the first and second batch processing chambers 120, 130 are configured to process the same number of wafers in the same batch time (x=y) and the first and second single wafer processing chambers (i.e., pre-clean chambers 140, 150) are configured to perform the same process in the same amount of time (1/x=1/y).

The processing platform 100 can include a controller 195 connected to the robot 117 (the connection is not shown). The controller 195 can be configured to move wafers between the pre-clean chamber 140 and the first batch processing chamber 120 with a first arm 118 of the robot 117. In some embodiments, the controller 195 is also configured to move wafers between the second single wafer processing chamber 150 and the second batch processing chamber 130 with a second arm 119 of the robot 117.

The processing platform 100 can also include a first buffer station 151 connected to a fifth side 115 of the central transfer station 110 and/or a second buffer station 152 connected to a sixth side 116 of the central transfer station 110. The first buffer station 151 and second buffer station 152 can perform the same or different functions. For example, the buffer stations may hold a cassette of wafers which are processed and returned to the original cassette, or the first buffer station 151 may hold unprocessed wafers which are moved to the second buffer station 152 after processing. In some embodiments, one or more of the buffer stations are configured to pre-treat, pre-heat or clean the wafers before and/or after processing.

In some embodiments, the controller 195 is configured to move wafers between the first buffer station 151 and one or more of the pre-clean chamber 140 and the first batch processing chamber 120 using the first arm 118 of the robot 117. In some embodiments, the controller 195 is configured to move wafers between the second buffer station 152 and one or more of the second single wafer processing chamber 150 or the second batch processing chamber 130 using the second arm 119 of the robot 117.

The controller 195 may be coupled to various components of the processing platform 100 to control the operation thereof. The controller 195 can be a single controller that controls the entire processing platform 100, or multiple controllers that control individual portions of the processing platform 100. For example, the processing platform 100 may include separate controllers for each of the individual processing chambers, central transfer station, factory interface and robots. In some embodiments, the controller 195 includes a central processing unit (CPU) 196, a memory 197, and support circuits 198. The controller 195 may control the processing platform 100 directly, or via computers (or controllers) associated with particular process chamber and/or support system components. The controller 195 may be one of any form of general-purpose computer processor that can be used in an industrial setting for controlling various chambers and sub-processors. The memory 197 or computer readable medium of the controller 195 may be one or more of readily available memory such as random access memory (RAM), read only memory (ROM), floppy disk, hard disk, optical storage media (e.g., compact disc or digital video disc), flash drive, or any other form of digital storage, local or remote. The support circuits 198 are coupled to the CPU 196 for supporting the processor in a conventional manner. These circuits include cache, power supplies, clock circuits, input/output circuitry and subsystems, and the like. One or more processes may be stored in the memory 198 as software routine that may be executed or invoked to control the operation of the processing platform 100 or individual processing chambers in the manner described herein. The software routine may also be stored and/or executed by a second CPU (not shown) that is remotely located from the hardware being controlled by the CPU 196. The controller 195 can include one or more configurations which can include any commands or functions to control flow rates, gas valves, gas sources, rotation, movement, heating, cooling, or other processes for performing the various configurations.

The processing platform 100 may also include one or more slit valves 160 between the central transfer station 110 and any of the processing chambers. In the embodiment shown, there is a slit valve 160 between each of the processing chambers 120, 130, 140, 150 and the central transfer station 110. The slit valves 160 can open and close to isolate the environment within the processing chamber from the environment within the central transfer station 110. For example, if the processing chamber will generate plasma during processing, it may be helpful to close the slit valve for that processing chamber to prevent stray plasma from damaging the robot in the transfer station.

In some embodiments, the processing chambers are not readily removable from the central transfer station 110. To allow maintenance to be performed on any of the processing chambers, each of the processing chambers may further include a plurality of access doors 170 on sides of the processing chambers. The access doors 170 allow manual access to the processing chamber without removing the processing chamber from the central transfer station 110. In the embodiment shown, each side of each of the processing chamber, except the side connected to the transfer station, have an access door 170. The inclusion of so many access doors 170 can complicate the construction of the processing chambers employed because the hardware within the chambers would need to be configured to be accessible through the doors.

The processing platform of some embodiments includes a water box 180 connected to the transfer station 110. The water box 180 can be configured to provide a coolant to any or all of the processing chambers. Although referred to as a “water” box, those skilled in the art will understand that any coolant can be used.

In some embodiments, the size of the processing platform 100 allows for the connection to house power through a single power connector 190. The single power connector 190 attaches to the processing platform 100 to provide power to each of the processing chambers and the central transfer station 110.

The processing platform 100 can be connected to a factory interface 102 to allow wafers or cassettes of wafers to be loaded into the platform 100. A robot 103 within the factory interface 102 can be moved the wafers or cassettes into and out of the buffer stations 151, 152. The wafers or cassettes can be moved within the platform 100 by the robot 117 in the central transfer station 110. In some embodiments, the factory interface 102 is a transfer station of another cluster tool.

In some embodiments, the second pre-clean chamber 150 is a plasma processing chamber. The plasma processing chamber of some embodiments exposes the substrate to a decoupled plasma comprising helium. The inventors have surprisingly found that a decoupled helium plasma improves the wet etch rate of a Si/C/O/N film.

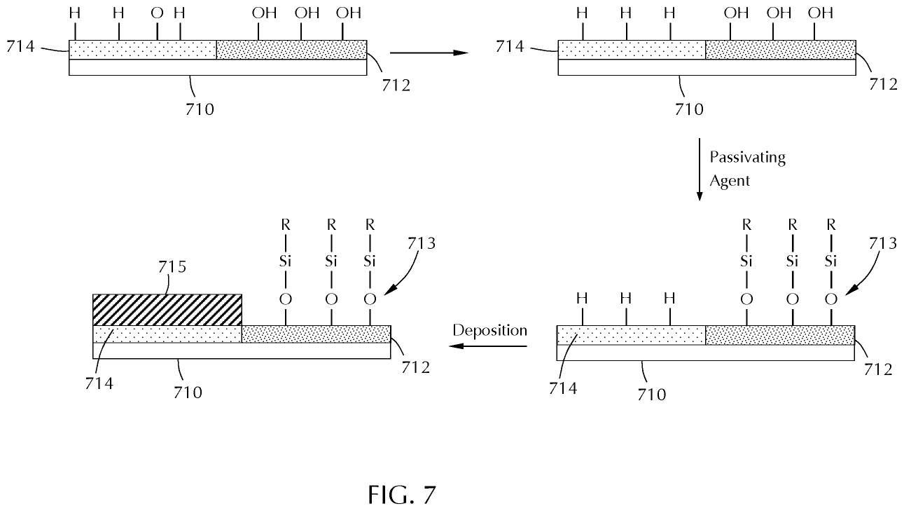

FIG. 7 shows a representative method in accordance with one or more embodiment of the disclosure. A substrate 710 has a first substrate surface 712 with a hydroxyl-terminated surface. The substrate 710 also has a second substrate surface 714 with a hydrogen-terminated surface. In some embodiments, the second surface 714 has some native oxide formed thereon, as shown in FIG. 7. While the embodiment illustrated by FIG. 7 shows simple single bonds to the substrate surface, those skilled in the art will understand that this is merely for illustrative purposes and understand that the surface atom bonding is not as simple as illustrated. For example, an oxide surface can be a bridged oxygen atom bonded to more than one silicon atom and that the stoichiometry of the surface and bulk composition are not necessarily one-to-one.

The first surface 712 and second surface 714 can be any suitable surfaces for selective deposition. In some embodiments, the first surface comprises a dielectric surface with —OH ending groups and the second surface comprises a silicon surface with Si—H groups with or without native oxide. In some embodiments, the first surface comprises a dielectric surface with —OH ending groups and the second surface comprises a metal surface with or without a native oxide. In some embodiments, the first surface comprises a metal oxide surface with —OH end groups and the second surface comprises a silicon surface with Si—H groups with or without native oxide. In some embodiments, the first surface comprises a metal oxide surface with —OH end groups and the second surface comprises a clean metal surface without native oxide.

If a native oxide is present on the second surface 714, removal of the native oxide may allow for a more effective selective deposition process. Exposing the substrate 710 to an etch process can remove the native oxide from the second surface 714. The etch process can be a wet etch process (e.g., exposure to dilute HF (1%)) or a dry etch process (e.g., exposure to a plasma). In some embodiments, the etch process is a plasma-based process. In some embodiments, the plasma-based etch process comprises exposing the substrate to a plasma of ammonia and hydrofluoric acid.

In some embodiments, removing the native oxide from the second surface 714 provides a surface with substantially only hydrogen terminations. As used in this manner, the term “substantially only hydrogen terminations” means that the surface terminations are hydrogen for greater than or equal to about 98% of the surface area. In some embodiments, removing the native oxide from the second surface 714 provides a surface with substantially no oxygen terminations. As used in this manner, the term “substantially no oxygen terminations” means that the surface terminations comprise less than about 2% of the surface area comprises oxygen atoms.

In one or more embodiments, the process used to remove the native oxides from the second surface 714 also oxidizes the first surface 712 to provide a surface with substantially no hydrogen terminations. As used in this manner, the term “substantially no hydrogen terminations” means that the surface terminations of the stated surface are hydrogen for less than or equal to about 2% of the surface area. In some embodiments, the first surface 712 comprises substantially only hydroxyl terminations. As used in this manner, the term “substantially only hydroxyl terminations” means that the surface terminations for the subject surface are hydroxyl groups for greater than or equal to about 98% of the surface area.

The substrate 710, including the first surface 712 and second surface 714, can be exposed to a passivation agent to react with the hydroxyl-terminated surface to form a blocking layer 713. The passivation agent of some embodiments comprises an alkylsilane. In some embodiments, has a general formula SiR₄, where each R is independently a C1-C6 alkyl, a substituted or unsubstituted amine, a substituted or unsubstituted cyclic amine.

In some embodiments, the alkylsilane comprising substantially no Si—H bonds. As used in this manner, the term “substantially no Si—H bonds” means that the passivating agent comprises less than about 1% Si—H bonds based on the total number of silicon bonds. The passivating agent of some embodiments, forms surface termination —OSiRₓ on the first surface 712, replacing the —OH terminations. In some embodiments, the passivating agent comprises one or more of 1-(trimethylsilyl)pyrrolidine or bis(dimethylamino)dimethylsilane.

In some embodiments, the alkylsilane comprises at least one substituted or unsubstituted cyclic amine with a ring having in the range of 4 to 10 atoms. In some embodiments, the alkylsilane comprises a cyclic amine that has one nitrogen atom. In some embodiments, the cyclic amine has no more than one nitrogen atom and no less than one nitrogen atom. In one or more embodiments, the cyclic amine comprises pyrrolidine in which the nitrogen atom of the pyrrolidine is bonded to the silicon atom of the alkylsilane. In some embodiments, the alkylsilane comprises 1-(trimethylsilyl)pyrrolidine. In one or more embodiments, the alkylsilane consists essentially of 1-(trimethylsilyl)pyrrolidine. As used in this manner, the term “consists essentially of” means that the alkylsilane is greater than or equal to about 98% 1-(trimethylsilyl)pyrrolidine on a molecular basis.

The substrate can be exposed to the passivating agent at any suitable temperature and pressure. In some embodiments, the substrate is exposed to the passivating agent at a temperature in the range of about 50° C. to about 500° C., or in the range of about 100° C. to about 400° C. In some embodiments, the substrate is exposed to the passivating agent at a pressure in the range of about 30 Torr to about 120 Torr, or in the range of about 40 Torr to about 100 Torr, or in the range of about 50 Torr to about 90 Torr. In one or more embodiments, the substrate is exposed to the passivating agent in a thermal process without plasma.

After forming the blocking layer 713, the substrate 710 is exposed to one or more deposition gases to deposit a film 715 on the second surface 714 selectively over the first surface 712. As used in this regard, the term “selectively over” means that the film is formed on the second surface to a greater extent than the film can be formed on the first surface. For example, the film 715 can be formed on the second surface greater than or equal to 20 times, 30 times, 40 times or 50 times thicker than the film is formed on the first surface.

Formation of the film 715 can occur by any suitable technique including, but not limited to, atomic layer deposition. In some embodiments, the film 715 is formed in a batch processing chamber, like that shown in FIGS. 2 through 6. For example, the film 715 may be formed by sequential exposure to a silicon precursor and a reactant. The film 715 of some embodiments comprises one or more of SiN, SiO, SiON, SiC, SiCO, SiCN or SiCON. In some embodiments, the film 715 comprises silicon and one or more of oxygen, carbon or nitrogen atoms. In some embodiments, the film 715 is doped with one or more of B, As or P in an amount up to about two percent on an atomic basis.

In some embodiments, the silicon precursor comprises a silicon halide and the reactant comprises ammonia. In some embodiments, the silicon precursor comprises an organic silicon compound with or without halogen atoms. In some embodiments, the reactant comprises a nitrogen contributing species, an oxygen contributing species and/or a carbon contributing species. In some embodiments, the silicon precursor contributes one or more of nitrogen, oxygen or carbon to the film 715.

In a batch processing chamber, the substrate can be exposed to the silicon precursor and reactant in alternating process regions of the processing chamber. Referring to FIG. 6, for example, process regions 350a, 350c, 350e, 350g may expose the substrate surface to the silicon precursor and process regions 350b, 350d, 350f, 350h may expose the substrate surface to the reactant, so that each rotation of a substrate around the processing chamber exposes the substrate surface to four cycles of silicon precursor/reactant.

The substrate can be exposed to the passivating agent in any suitable process chamber. In some embodiments, the substrate is exposed to the passivating agent in the pre-clean chamber. In some embodiments, the substrate is exposed to the passivating agent in a separate passivating chamber. In some embodiments, the substrate is exposed to the passivating agent in the batch processing chamber. For example, the process regions of the batch processing chamber can be changed so that the reactive gas flowing in the process regions is replaced with the passivating agent. After forming the blocking layer, the flow of the passivating agent in the process regions can be replaced with the silicon precursor and the reactant.

The film thickness can be deposited to a predetermined amount. After some time, the film 715 may begin to deposit on the first surface 712 even though the blocking layer 713 is present. Without being bound by any particular theory of operation, it is believed that the blocking layer 713 may be removed by the repeated exposures to the deposition reactants. To increase the thickness of the film 715 and maintain the selectivity, the blocking layer 713 may be replenished periodically. In some embodiments, the substrate is exposed to the passivating agent after no more than 20, 30, 40, 50, 60, 70, 80, 90 or 100 atomic layer deposition cycles to deposit the film 715. In some embodiments, the substrate is exposed to the passivating agent after formation of the film 715 to a thickness in the range of about 30 Å to about 100 Å, or after formation of the film 715 to a thickness up to about 20 Å, 30 Å, 40 Å, 50 Å, 60 Å or 70 Å.

Regeneration of the blocking layer 713 can be done by any suitable process. For example, the surface of the substrate can be purged with an inert gas (e.g., N₂ or He) for a time in the range of about 10 minutes to about 60 minutes at a pressure in the range of about 1 Torr to about 30 Torr. After purging the surface, the substrate can be exposed to the passivating agent again to regenerate the blocking layer 713. In some embodiments, the surface is purged for a time in the range of about 15 minutes to about 50 minutes, or a time in the range of about 20 minutes to about 40 minutes. In some embodiments, the surface is purged at a pressure in the range of about 10 Torr to about 25 Torr, or in the range of about 15 Torr to about 20 Torr.

In some embodiments, the blocking layer 713 is regenerated by first etching the whole surface of the substrate followed by exposure to the passivating agent. The etching process can be the same process used to pre-clean the surface or can be a different etching process.

The film 715 can be formed at any suitable temperature. In some embodiments, the film 715 is formed at a temperature in the range of about 200° C. to about 550° C., or in the range of about 300° C. to about 500° C., or in the range of about 350° C. to about 450° C. In some embodiments, the film 715 is formed by a thermal process without plasma exposure. In some embodiments, the film 715 is formed by a plasma enhanced process.

The film 715 deposited may have film properties that can be optimized or improved by post-deposition processing. For example, a silicon nitride film deposited may have a high wet etch rate. Exposing the film to a post-deposition process can be used to improve the wet etch rate of the deposited film 715. In some embodiments, the post-deposition process improves a quality of the film. In some embodiments, the quality of the film improved comprises one or more of the wet etch rate, refractive index, density or hydrogen concentration.

The post-deposition process of some embodiments comprises exposing the substrate surface to a decoupled plasma. The decoupled plasma of one or more embodiments comprises helium. In some embodiments, the decoupled plasma consists essentially of helium. As used in this regard, the term “consists essentially of helium” means that the plasma comprises greater than or equal to about 95 atomic percent helium. The treatment pressure of some embodiments is in the range of about 1 mTorr to about 1 Torr. Lower pressures may be used for isotropic treatment of high aspect ratio structures. Wafer temperature during treatment can range from about room temperature to about 500° C.

In some embodiments, the processing platform has an environment that does not readily oxidize the substrate surface after cleaning. As used in this regard, the term “environment” refers to the ambient conditions within at least the central transfer station 110. The environment of the processing platform of some embodiments also includes any processing chamber used in the deposition process. For example, if two processing chambers are used in the process, the “environment” might include the two processing chambers and the central transfer station. In some embodiments, the environment of the processing platform comprises water vapor. The water vapor can be mixed with an inert gas or neat. In some embodiments, the water vapor is present in an inert gas in an amount in the range of about 0.1% to about 90% by weight. In some embodiments, the water vapor is present in an amount in the range of about 1% to about 80%, or in the range of about 2% to about 70%, or in the range of about 3% to about 60%, or in the range of about 4% to about 50%, or in the range of about 5% to about 40%, or in the range of about 10% to about 20% by weight. In some embodiments, the environment comprise one or more of nitrogen, hydrogen, helium, argon, krypton, neon or xenon with water vapor in an amount greater than or equal to about 0.1%, 0.5, 1%, 2%, 3%, 4%, 5%, 6%, 7%, 8%, 9%, 10%, 12%, 14, 16%, 18% or 20%.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present disclosure are the Centura® and the Endura®, both available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A processing platform comprising:
a central transfer station having a robot therein, the central transfer station having a plurality of sides;
a pre-clean chamber connected to a first side of the central transfer station, the pre-clean chamber configured to perform one or more of a wet etch process or a dry etch process; and
a batch processing chamber connected to a second side of the central transfer station, the batch processing chamber having a plurality of process regions separated by gas curtains, the batch processing chamber including a susceptor assembly configured to support and rotate a plurality of substrates around a central axis so that the substrates move through the plurality of process regions,
wherein at least the central transfer station has an environment comprising greater than or equal to about 0.1% by weight water vapor in an inert gas.

2. The processing platform of claim 1, further comprising a plasma chamber connected to a third side of the central transfer station, the plasma chamber configured to produce a decoupled plasma.

3. The processing platform of claim 1, wherein the plurality of process regions comprise a silicon precursor and a reactant comprising one or more of an oxygen providing reactant, a nitrogen providing reactant or a carbon providing reactant.

4. The processing platform of claim 3, wherein the plurality of process regions further comprise a passivation region comprising a passivation agent.

5. The processing platform of claim 1, wherein one or more of the pre-clean chamber, the batch processing chamber or a passivation chamber is configured to deliver a passivation agent comprising an alkylsilane.

6. The processing platform of claim 5, wherein the alkylsilane has a general formula SiR₄, where each R is independently a C1-C6 alkyl, a substituted or unsubstituted amine, a substituted or unsubstituted cyclic amine, the alkylsilane comprising substantially no Si—H bonds.

7. The processing platform of claim 6, wherein the alkylsilane comprises at least one substituted or unsubstituted cyclic amine with a ring having in a range of 4 to 10 atoms.

8. The processing platform of claim 7, wherein the cyclic amine has one nitrogen atom.

9. The processing platform of claim 8, wherein the cyclic amine comprises pyrrolidine and an Si—N bond.

10. The processing platform of claim 9, wherein the alkylsilane comprises 1-(trimethylsilyl)pyrrolidine.

11. The processing platform of claim 1, further comprising a controller connected to the robot, the pre-clean chamber and batch processing chamber, the controller configured to a substrate from the pre-clean chamber to the batch processing chamber.

12. The processing platform of claim 1, further comprising a slit valve between the central transfer station and each of the pre-clean chamber and the batch processing chamber.

13. The processing platform of claim 12, wherein the batch processing chamber comprises a plurality of access doors on sides of the batch processing chamber to allow manual access to the batch processing chamber without removing the batch processing chamber from the central transfer station.
